(19) United States
(12) Patent Application Publication
(10) Pub. No.: US 2025/0022819 A1
(43) Pub. Date: Jan. 16, 2025

(54) METHODS FOR FORMING CONDUCTIVE STRUCTURES BETWEEN TWO SUBSTRATES

(71) Applicant: STATS ChipPAC Pte. Ltd, Singapore (SG)

(72) Inventors: KiRak SON, Incheon (KR); JungHwan JANG, Incheon (KR); KyungHan RYU, Incheon (KR); MyongSuk KANG, Incheon (KR); JaeSeong CHOI, Gyeonggi-do (KR); YoungJoon YOON, Seoul (KR)

(21) Appl. No.: 18/765,338

(22) Filed: Jul. 8, 2024

(30) Foreign Application Priority Data
Jul. 13, 2023 (CN) 202310860505.4

(51) Int. Cl. H01L 23/00

(52) U.S. Cl. CPC H01L 24/03; H01L 24/80; H01L 2224/0311; H01L 2224/0312; H01L 2224/0347; H01L 2224/80895; H01L 2224/80896

(57) ABSTRACT

A method for forming conductive structures between two substrates is disclosed. The method comprises: forming a first patterned base layer and a second patterned base layer on a first substrate and a second substrate, wherein the first and second patterned base layers comprise through-holes; forming first and second metallic contact structures in the through holes of the first and second patterned base layer, wherein both the first and second metallic contact structures have front surfaces that are higher than respective front surfaces of the first and second patterned base layers; forming a first and a second patterned polymer layer on the respective front surfaces of the first and second patterned base layer, wherein the first and second metallic contact structures are exposed from and higher than respective front surfaces of the first and second patterned polymer layer; passivating the front surfaces of the first and second metallic contact structures; bonding the front surfaces of the first and second metallic contact structures with each other; and bonding the front surfaces of the first and second patterned polymer layers with each other after the front surfaces of the first and second metallic contact structures are bonded with each other.

### TECHNICAL FIELD

The present application generally relates to semiconductor technologies, and more particularly, to a method for forming conductive structures between two substrates.

### BACKGROUND OF THE INVENTION

Hybrid bonding is a chip-level interconnection technology that can enhance the density of integrated chip packages, resulting in high performance, small form factors and lower consumption for the integrated chip packages. Before a bonding process to form hybrid bonding, a chemical-mechanical polishing (CMP) process is generally required to planarize the surfaces of the integrated chip packages or other substrates. However, metal dishing or oxide erosion may occur after the CMP process, which may impair the quality of the hybrid bonding. Therefore, a need exists for further improvement to hybrid bonding technologies.

### SUMMARY OF THE INVENTION

An objective of the present application is to provide a hybrid bonding technology for forming conductive structures between two substrates.

According to an aspect of the present application, a method for forming conductive structures between two substrates is disclosed. The method comprises: forming a first patterned base layer and a second patterned base layer on respective front surfaces of a first substrate and a second substrate, wherein the first and second patterned base layers comprise through-holes that expose partially the respective front surfaces of the first and second substrates; forming first metallic contact structures in the through holes of the first patterned base layer and second metallic contact structures in the through holes of the second patterned base layer, wherein both the first metallic contact structures and the second metallic contact structures have front surfaces that are higher than respective front surfaces of the first and second patterned base layers; forming a first patterned polymer layer and a second patterned polymer layer on the respective front surfaces of the first patterned base layer and the second patterned base layer, wherein the first and second metallic contact structures are exposed from and higher than respective front surfaces of the first patterned polymer layer and the second patterned polymer layer; passivating the front surfaces of the first and second metallic contact structures; bonding the front surfaces of the first and second metallic contact structures with each other; and bonding the front surfaces of the first and second patterned polymer layers with each other after the front surfaces of the first and second metallic contact structures are bonded with each other.

According to another embodiment of the present application, a method for forming conductive structures between two substrates is disclosed. The method comprises: forming a first patterned base layer and a second patterned base layer on respective front surfaces of a first substrate and a second substrate, wherein the first and second patterned base layers comprise through-holes that expose partially the respective front surfaces of the first and second substrates; forming first metallic contact structures in the through holes of the first patterned base layer and second metallic contact structures in the through holes of the second patterned base layer, wherein both the first metallic contact structures and the second metallic contact structures have front surfaces that are higher than respective front surfaces of the first and second patterned base layers; forming a first patterned polymer layer and a second patterned polymer layer on the respective front surfaces of the first patterned base layer and the second patterned base layer, wherein the first and second metallic contact structures are exposed from and lower than respective front surfaces of the first patterned polymer layer and the second patterned polymer layer; forming solder materials on the respective front surfaces of the first and second metallic contact structures; bonding the front surfaces of the first and second patterned polymer layers with each other; and bonding the first and second metallic contact structures with each other through the solder materials thereon after the front surfaces of the first and second patterned polymer layers are bonded with each other.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to IM illustrate a method for forming conductive structures between two substrates according to an embodiment of the present application.

FIGS. 2A to 2C illustrate some steps of a method for forming conductive structures between two substrates according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Conventional hybrid bonding processes require chemical mechanical planarization (CMP) and chemical vaporization deposition (CVD) treatments which may introduce undesired defects to substrate surfaces to be bonded together. The inventors of the present application propose a new hybrid bonding process that does not require using the CMP treatment for surface planarization, which can form better conductive structures between two substrates at a relatively low cost. Also, the hybrid bonding can be implemented utilizing different thermal expansion characteristics of the materials (i.e., a conductive material and an insulative material) at the bonding surface.

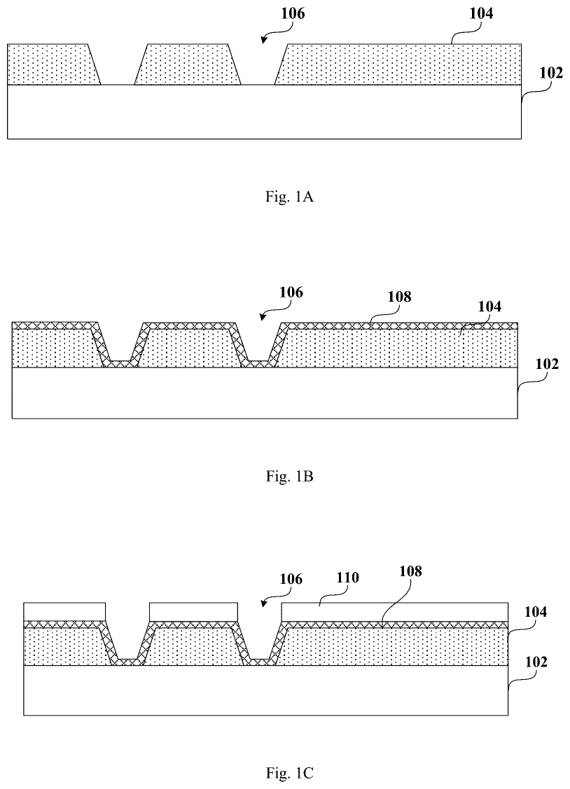

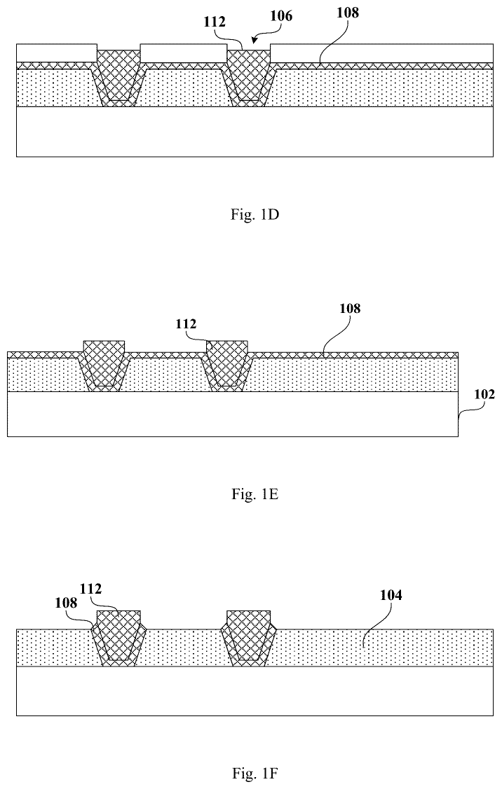

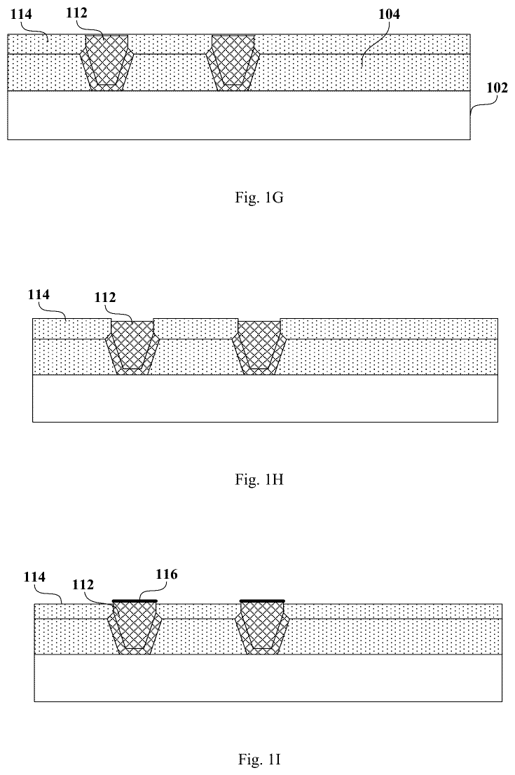

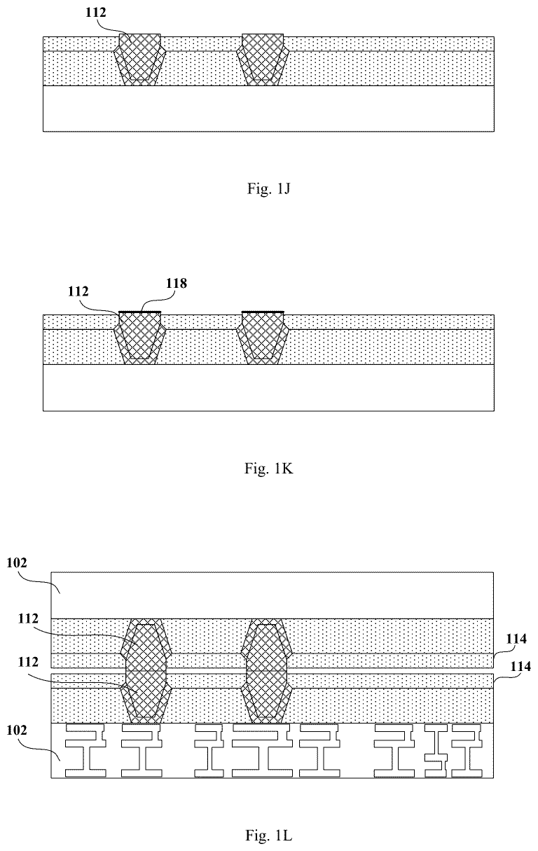

FIGS. 1A to 1M illustrate a method for forming conductive structures between two substrates according to an embodiment of the present application. It can be appreciated that two substrates are desired to be bonded together through hybrid bonding, and thus similar or identical preparation steps of the method may be performed on both of the two substrates. For illustration purpose, some of the steps are illustrated with reference to only one of the substrates, but it can be appreciated that the other substrate can be treated similarly.

As shown in FIG. 1A, a first substrate 102 is provided. The first substrate 102 may include a device substrate with conductive patterns (not shown) formed on its front surface, or an interconnect substrate such as a redistribution layer (RDL) substrate or an interposer substrate with conductive patterns (not shown) formed on its front surface as well. The device substrate may include semiconductor chips or similar devices. The conductive patterns of the first substrate 102 are desired to be electrically coupled to conductive patterns of a second substrate such that certain structures, components or devices of the two substrates can be electrically coupled together. Similarly, the second substrate can be a device substrate or an interconnect substrate. In some embodiments, the first and second substrates may include a printed circuit board (PCB), a carrier substrate, a semiconductor substrate with electrical interconnections, or a ceramic substrate. In some other examples, the substrates may include a laminate interposer, a strip interposer, a leadframe, or other suitable substrates. In some embodiments, the substrates may include a plurality of interconnection structures that can provide connectivity for electronic components mounted on the substrates. The interconnection structures may include one or more of Cu, Al, Sn, Ni, Au, Ag, or any other suitable electrically conductive materials. In some examples, the interconnection structures may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures.

Still referring to FIG. 1A, a base layer 104 may be formed on the front surface of the first substrate 102. The base layer 104 may be formed of an insulating material such as a polymer material, which provides insulation between the substrates to be bonded together as well as between conductive structures to be formed within the base layer 104. In some embodiment, the base layer 104 may formed of a photosensitive polymer, such that it can be patterned directly using photolithography. In some other embodiments, a photoresist layer may be formed on the base layer 104 for patterning of the base layer 104, and can be removed after the base layer 104 is patterned. As illustrated in FIG. 1A, through-holes 106 can be formed in the patterned base layer 104, which can expose partially the front surface of the first substrate 102, for example, at the conductive patterns topmost of the first substrate 102. The through-holes 106 can be formed when the base layer 104 is being patterned.

Next, as shown in FIG. 1B, a seed layer 108 may be formed on the first substrate 102, which covers a front surface of the base layer 104 and the exposed front surface of the first substrate 102 by the through holes 106. The seed layer 108 can assist subsequent formation of conductive materials in the through holes 106. In some embodiment, the seed layer 108 can be formed of a composition of titanium and copper, and may be formed on the first substrate 102 using a physical vaporization process such as sputtering.

Afterwards, as shown in FIG. 1C, a patterned photoresist layer 110 may be formed on the first substrate 102 to cover a portion of the seed layer 108 on the front surface of the base layer 104 but expose the other portion of the seed layer 108 inside the through holes 106. As shown in FIG. 1D, a metallic material such as copper may be filled within the through holes 106 to form respective metallic contact structures 112 therein. In some embodiments, the metallic material may be filled in the through holes using electroplating. Since the seed layer 108 is partially covered by the patterned photoresist layer 110, the metallic material may be formed only in the through holes 106 but not on the photoresist layer 110. In some alternative embodiments, the metallic material may be filled using sputtering, and thus covering both the patterned photoresist layer 110 and the exposed seed layer 108.

Next, as shown in FIG. 1E, the patterned photoresist layer may be removed from the first substrate 102, leaving the seed layer 108 and the metallic contact structures 112 remained on the first substrate 102. In some embodiments where the metallic material is also formed on the patterned photoresist layer, the metallic material outside of the through holes can be lift off with the removed photoresist layer.

Afterwards, as shown in FIG. 1F, the seed layer 108 on the front surface of the base layer 104 may be etched off, to expose the base layer 104. If the seed layer 108 is not etched off from the front surface of the base layer 104, the residuals of the seed layer 108 may form undesired horizontal conductive structures, which may impair the insulation performance of the base layer 104. Since the seed layer 108 has a thickness that is much smaller than that of the metallic conductive structures 112, the metallic conductive structures 112 can maintain a generally complete structure after the seed layer 108 is etched off. It can be appreciated that the portion of the seed layer 108 filled in the through holes and under the metallic conductive structures 112 may not be removed.

Next, as shown in FIG. 1G, a polymer layer 114 may be formed on the first substrate 102, to cover the respective front surfaces of the patterned base layer 104 and the metallic contact structures 112. In some embodiments, the polymer layer 114 may be formed of a photosensitive polymer such that it can be patterned directly using photolithography. In some other embodiments, a photoresist layer may be formed on the polymer layer 114 for patterning of the polymer layer 114, which may be removed after the polymer layer 114 is patterned.

Next, as shown in FIG. 1H, the polymer layer 114 may be patterned, e.g., using photolithography, to expose the metallic contact structures 112. In some embodiments, since the polymer layer 114 previously covers the metallic contact structures 112, a front surface of the patterned polymer layer 114 is higher than the front surfaces of the metallic contact structures 112.

Next, as shown in FIG. 1I, the patterned polymer layer 114 may be descummed, to remove undesired contaminants or residuals topmost the polymer layer 114. In particular, the descumming treatment may be polymer-specific, and thus the metallic contact structures 112 are generally complete and not affected by the descumming treatment, except that metallic oxides 116 may be formed on the front surfaces of the metallic contact structures 112. Furthermore, the descumming treatment may remove a portion of the patterned polymer layer 114, such that the front surface of the patterned polymer layer 114 may be lowered, for example, to a level that is lower than the front surfaces of the metallic contact structures 112. In some embodiment, the descumming treatment may be implemented in an atmosphere of oxygen, or in an atmosphere of oxygen and nitrogen. The polymer materials of the polymer layer 114 may be etched by the oxygen and thus removed from the substrate. In some preferred embodiments, the atmosphere of oxygen and nitrogen is preferred because the mixed gas of oxygen and nitrogen has a higher etching rate for polymer materials than oxygen.

Afterwards, the metallic oxides on the front surfaces of the metallic contact structures 112 may be etched off, for example, using plasma treatment, as shown in FIG. 1J. In an example, during the plasma treatment, Ar ions may be bombarded onto the front surfaces of the metallic contact structures 112, such that the metallic oxides and some other contaminants may be removed, leaving a clean surface for the subsequent bonding process. It can be seen that the planarization of the metallic contact structures 112 and the patterned polymer layer 114 can be performed with plating, etching and descumming processes, instead of the CMP process which is relatively high-cost.

Next, as shown in FIG. 1K, the front surfaces of the metallic contact structures 112 may be passivated, for example, using another plasma treatment. In some embodiments, nitrogen can be used to passivate the front surfaces of the metallic contact structures 112. After the treatment, nitrides 118 such as Cu₄N may be formed on the front surfaces of the metallic contact structures 112, which may prevent formation of metallic oxides but may not affect the subsequent bonding process.

As mentioned above, the above steps shown in FIGS. 1A to 1K may be performed similarly to another substrate such as the second substrate to be bonded with the first substrate 102. Next, as shown in FIG. 1L, the two substrates 102, i.e., the first and second substrates, may be moved close to each other with their front surfaces facing towards each other. In particular, the metallic contact structures 112 on the two substrates 102 may be aligned with each other. Then, the front surfaces of the metallic contact structures 112 on both substrates 102 may be in contact with each other, and a bonding process to the metallic contact structures 112 may be performed. For example, the metallic contact structures 112 may be pressed against each other at a first temperature. The first temperature for bonding the metallic contact structures 112 may vary depending on the characteristics and material of the metallic contact structures 112. In some examples where the metallic contact structures 112 are formed of copper, the first temperature may be around 250 to 300 centi-degrees. At such temperature, copper nitride may be decomposed while copper-copper direct bonding can be implemented.

Furthermore, since the front surfaces of the metallic contact structures 112 are generally higher than the front surfaces of the respective patterned polymer layers 114, the patterned polymer layers 114 on both substrate 102 may not be in contact with each other during the bonding process of the metallic contact structures 112. In that case, a separate bonding process may be performed on the patterned polymer layers 114. As shown in FIG. 1M, after the front surfaces of the first and second metallic contact structures 112 are bonded with each other, the front surfaces of the patterned polymer layers on both substrates 102 can be bonded with each other at a second temperature. The second temperature is different from the first temperature. In some embodiments, the second temperature may be higher than the first temperature. For example, the polymer material may be polyimide or polybenzoxazole (PBO), which can be photosensitive. The polymer material may have a coefficient of thermal expansion greater than copper or similar metallic materials, such that the patterned polymer layers 114 may expand in an amount greater than the metallic contact structures 112, when they are heated to a high temperature. The polymer material of the patterned polymer layers 114 may expand at the second temperature to the extent that the patterned polymer layers 114 can be in contact with each other and sufficiently cured. In some examples, the second temperature can be 300 to 350 centi-degrees. It can be appreciated that the expansion of the patterned polymer layers 114 at the second temperature may not damage the bonded surfaces of the metallic contact structures 112, but may create a solid interface between patterned polymer layers 114. In this way, the hybrid bonding of the two substrates 102 may be implemented, with conductive structures that extend between them.

It can be appreciated that in the method shown in FIGS. 1A to IM, due to the descumming treatment shown in FIG. 1 which reduces a significant thickness of the patterned polymer layer 114, the front surface of the patterned polymer layer 114 are lower than the front surfaces of the metallic contact structures 112. But the greater expansion of the patterned polymer layers 114 ensures the joint and bonding between the opposite patterned polymer layers 114 subsequent to the bonding of the metallic contact structures 112. Nevertheless, the two materials, i.e., the polymer material and the metallic material, are desired to be bonded at two different temperatures to allow for better bonding of each of the two materials.

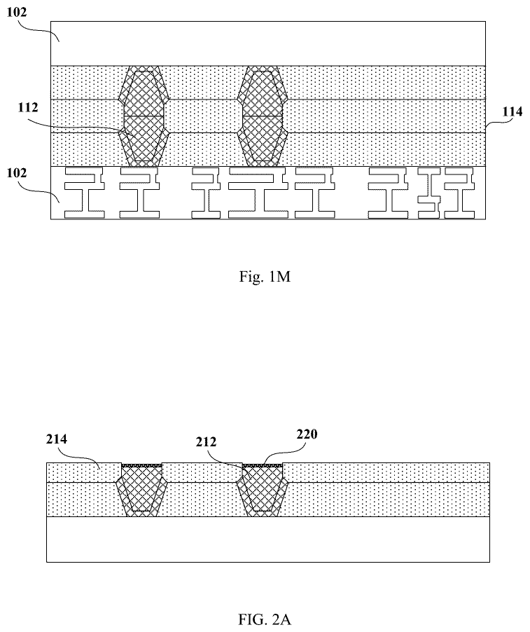

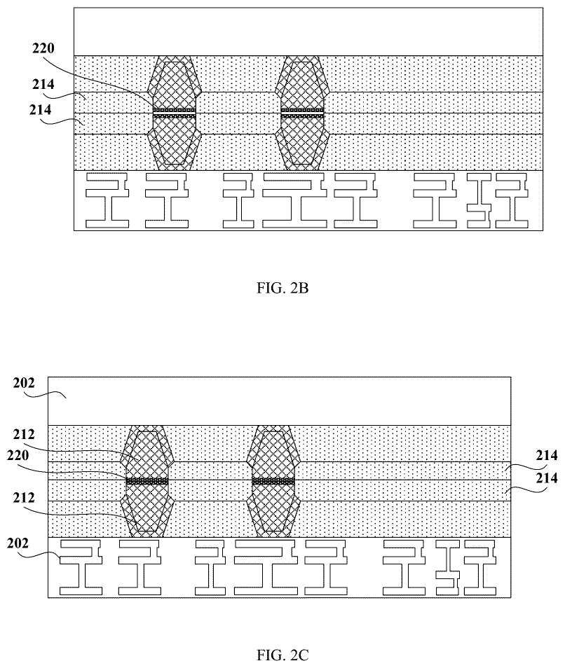

Some modifications may be made to the method shown in FIGS. 1A to IM. FIGS. 2A to 2C illustrate some steps of a method for forming conductive structures between two substrates according to another embodiment of the present application. Most of the steps of the method may be similar as those illustrated in the method shown in FIGS. 1A to IM. For example, the step shown in FIG. 2A may be performed subsequent to the step shown in FIG. 1H where the patterned polymer layer and the exposed metallic contact structures may be formed. In this embodiment, the polymer materials are bonded prior to the bonding of the metallic materials between two substrates.

As shown in FIG. 2A, a solder material 220 such as leadfree solder may be plated on front surfaces of exposed metallic contact structures 212. The solder material 220 may not cover front surfaces of a patterned polymer layer 214. In some embodiments, the patterned polymer layer 214 may include benzocyclobutene-based (BCB-based) polymers.

Next, as shown in FIG. 2B, two substrates, each having the surface structures shown in FIG. 2A, may be moved close to each other with their front surfaces facing towards each other. Then, the front surfaces of the patterned polymer layers 214 may be in contact with each other, and a bonding process to the patterned polymer layers 214 may be performed. For example, the patterned polymer layers 214 may be pressed against each other at a first temperature. The first temperature for bonding the patterned polymer layers 214 may vary depending on the characteristics and material of the patterned polymer layers 214. In the embodiment, the patterned polymer layers 214 may be BCB-based polymers which can be bonded at room temperature or another temperature which may be significantly lower than a reflow temperature of the solder material 220.

Next, as shown in FIG. 2C, after the patterned polymer layers 214 are bonded together and cured, the metallic contact structures 212 on both substrates 202 may be in contact with each other due to the shrinkage of the polymer layers 214 at a higher temperature, and a bonding process to the metallic contact structures 212 may be performed at a second temperature. For example, the second temperature may be about 250 to 300 centi-degrees at which the solder material 220 topmost of the metallic contact structures 212 may be reflowed, enhancing the bonding of the metallic contact structures 212. In this way, the two substrate 202 can be bonded together, with conductive structures extending between them.

It can be appreciated that the method shown in FIGS. 2A to 2C may be used when warpage of substrates occurs and the metallic contact structures cannot be bonded directly with each other. Since the polymer materials can be bonded at room temperature or another relatively lower temperature, the solder materials between the metallic contact structures may not reflow. In this way, solder bridges may not be formed between adjacent metallic contact structures.

While the method for forming conductive structures between two substrates of the present application is described in conjunction with corresponding figures, it will be understood by those skilled in the art that modifications and adaptations to the method may be made without departing from the scope of the present invention.

The discussion herein includes numerous illustrative figures that show various portions of a method for forming conductive structures between two substrates. For illustrative clarity, such figures do not show all aspects of each example semiconductor package. Any of the example optical sensor packages provided herein may share any or all characteristics with any or all other optical sensor packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming conductive structures between two substrates, the method comprising:
forming a first patterned base layer and a second patterned base layer on respective front surfaces of a first substrate and a second substrate, wherein the first and second patterned base layers comprise through-holes that expose partially the respective front surfaces of the first and second substrates;
forming first metallic contact structures in the through holes of the first patterned base layer and second metallic contact structures in the through holes of the second patterned base layer, wherein both the first metallic contact structures and the second metallic contact structures have front surfaces that are higher than respective front surfaces of the first and second patterned base layers;
forming a first patterned polymer layer and a second patterned polymer layer on the respective front surfaces of the first patterned base layer and the second patterned base layer, wherein the first and second metallic contact structures are exposed from and higher than respective front surfaces of the first patterned polymer layer and the second patterned polymer layer;
passivating the front surfaces of the first and second metallic contact structures;
bonding the front surfaces of the first and second metallic contact structures with each other; and
bonding the front surfaces of the first and second patterned polymer layers with each other after the front surfaces of the first and second metallic contact structures are bonded with each other.

2. The method of claim 1, wherein forming first metallic contact structures in the through holes of the first patterned base layer and second metallic contact structures in the through holes of the second patterned base layer comprises:
forming respective seed layers on front surfaces of the first and second patterned base layers and the exposed front surfaces of the first and second substrates;
forming respective patterned photoresist layers on the front surfaces of the first and second patterned base layers;
depositing a metallic material within the through holes of the first and second patterned base layers to form the first and second metallic contact structures; and
removing the patterned photoresist layers and the seed layers thereunder from the first and second patterned base layers, respectively.

3. The method of claim 1, wherein forming a first patterned polymer layer and a second patterned polymer layer on the respective front surfaces of the first patterned base layer and the second patterned base layer comprises:
forming a first polymer layer and a second polymer layer on the respective front surfaces of the first and second patterned base layers and on the respective front surfaces of the first and second metallic contact structures;
patterning the first polymer layer and the second polymer layer to form the first patterned polymer layer and the second patterned polymer layer that expose the respective front surfaces of the first and second metallic contact structures;
descumming the first patterned polymer layer and the second patterned polymer layer; and
etching metallic oxides on the front surfaces of the first and second metallic contact structures.

4. The method of claim 3, wherein the first polymer layer and the second polymer layer are photosensitive polymer layers.

5. The method of claim 1, wherein passivating the front surfaces of the first and second metallic contact structures comprises:
passivating the front surfaces of the first and second metallic contact structures using a plasma treatment.

6. The method of claim 1, wherein the bonding of the front surfaces of the first and second metallic contact structures is performed at a first temperature, and the bonding of the front surfaces of the first and second patterned polymer layers is performed at a second temperature higher than the first temperature.

7. A method for forming conductive structures between two substrates, the method comprising:
forming a first patterned base layer and a second patterned base layer on respective front surfaces of a first substrate and a second substrate, wherein the first and second patterned base layers comprise through-holes that expose partially the respective front surfaces of the first and second substrates;
forming first metallic contact structures in the through holes of the first patterned base layer and second metallic contact structures in the through holes of the second patterned base layer, wherein both the first metallic contact structures and the second metallic contact structures have front surfaces that are higher than respective front surfaces of the first and second patterned base layers;
forming a first patterned polymer layer and a second patterned polymer layer on the respective front surfaces of the first patterned base layer and the second patterned base layer, wherein the first and second metallic contact structures are exposed from and lower than respective front surfaces of the first patterned polymer layer and the second patterned polymer layer;
forming solder materials on the respective front surfaces of the first and second metallic contact structures;
bonding the front surfaces of the first and second patterned polymer layers with each other; and
bonding the first and second metallic contact structures with each other through the solder materials thereon after the front surfaces of the first and second patterned polymer layers are bonded with each other.

8. The method of claim 7, wherein forming first metallic contact structures in the through holes of the first patterned base layer and second metallic contact structures in the through holes of the second patterned base layer comprises:
forming respective seed layers on front surfaces of the first and second patterned base layers and the exposed front surfaces of the first and second substrates;
forming respective patterned photoresist layers on the front surfaces of the first and second patterned base layers;
depositing a metallic material within the through holes of the first and second patterned base layers to form the first and second metallic contact structures; and
removing the patterned photoresist layers and the seed layers thereunder from the first and second patterned base layers, respectively.

9. The method of claim 7, wherein forming a first patterned polymer layer and a second patterned polymer layer on the respective front surfaces of the first patterned base layer and the second patterned base layer comprises:
forming a first polymer layer and a second polymer layer on the respective front surfaces of the first and second patterned base layers and on the respective front surfaces of the first and second metallic contact structures; and
patterning the first polymer layer and the second polymer layer to form the first patterned polymer layer and the second patterned polymer layer that expose the respective front surfaces of the first and second metallic contact structures.

10. The method of claim 7, wherein the first and polymer layers comprise benzocyclobutene-based polymers.

11. The method of claim 7, wherein the first and second metallic contact structures are lower than the first and second patterned polymer layer, respectively, after forming the solder materials.

12. The method of claim 7, wherein the bonding of the front surfaces of the first and second patterned polymer layers is performed at a first temperature, and the bonding of the first and second metallic contact structures is performed at a second temperature higher than the first temperature.
